(19) United States
(12) Patent Application Publication
(10) Pub. No.: US 2026/0353724 A1
(43) Pub. Date: Nov. 5, 2026

(54) SEMICONDUCTOR PACAKGE AND METHOD OF FABRICATING THE SAME

(71) Applicant: Taiwan Semiconductor Manufacturing Company, Ltd., Hsinchu (TW)

(72) Inventors: Yu-Sheng Lin, Hsinchu County (TW); Jui Shen Chang, Taichung City (TW); Shih-Ting Hung, New Taipei City (TW); Jyun-Lin Wu, Hsinchu City (TW); Yao-Chun Chuang, Hsinchu City (TW)

(73) Assignee: Taiwan Semiconductor Manufacturing Company, Ltd., Hsinchu (TW)

(21) Appl. No.: 19/199,295

(22) Filed: May 5, 2025

(51) Int. Cl. H10D 62/10; H10P 34/42; H10P 52/00; H10W 90/00

(52) U.S. Cl. CPC H10D 62/117; H10P 34/42; H10P 52/00; H10W 90/792

(57) ABSTRACT

A semiconductor package includes a first die and a second die. The first die includes a first core portion and a protruding portion. The first core portion has first sidewalls, while protruding portion is protruding from the first core portion and extending beyond the first sidewalls, wherein the protruding portion has second sidewalls. The second die includes a second core portion and a retracted portion. The second portion has third sidewalls, while the retracted portion is retracted from the third sidewalls, wherein the retracted portion of the second die has fourth sidewalls, and the fourth sidewalls are aligned with the second sidewalls.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1A to FIG. 5 are schematic sectional views and top views of various stages in a method of fabricating a semiconductor package according to some exemplary embodiments of the present disclosure.

FIG. 6 to FIG. 7 are schematic sectional views of various stages in a method of fabricating a semiconductor package according to some other embodiments of the present disclosure.

FIG. 8 to FIG. 11 are schematic sectional views of various stages in a method of fabricating a semiconductor package according to some other embodiments of the present disclosure.

FIG. 12 is a schematic sectional view of a semiconductor package according to some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In three-dimensional integrated circuits (3DIC) having die-to-die bonding structures, laser grooving and die sawing techniques are generally applied to separate individual semiconductor packages. The laser grooving process is applied for cutting dielectric films to mitigate the mechanical saw induced damages. However, during the laser grooving process, a large amount of debris is usually generated in the heat affect zone of the laser due to a high energy of the applied laser. The formed debris has weak mechanical properties, which may be a starting point of crack propagation and thus causes package failure and reliability issues. In accordance with some embodiments of the present disclosure, a method of fabricating a semiconductor package is described, whereby an amount of debris formed in the package is reduced, and a package bending strength is increased.

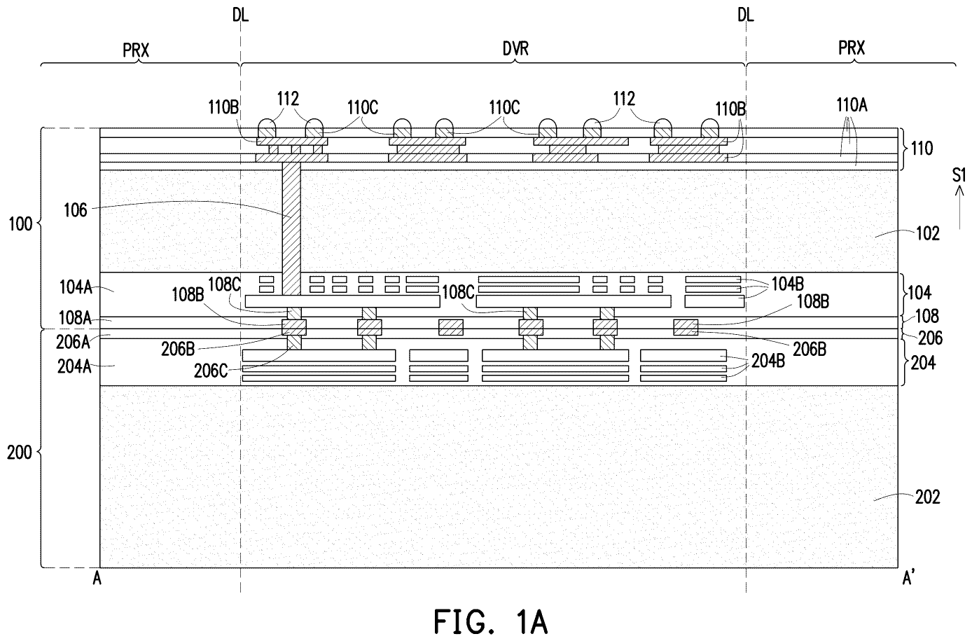

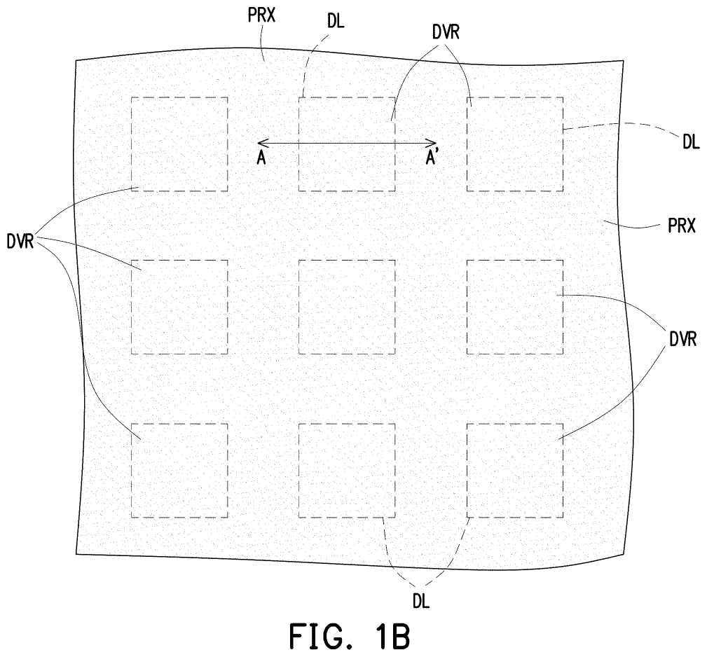

FIG. 1a to FIG. 4 are schematic sectional views and top views of various stages in a method of fabricating a semiconductor package according to some exemplary embodiments of the present disclosure. Referring to FIG. 1A, in some embodiments, one or a plurality of first dies 100 is bonded to one or a plurality of second dies 200 across device regions DVR and sawing regions PRX of a semiconductor wafer. For example, from a top view of the structure illustrated in FIG. 1B, and from FIG. 1A which is a sectional view taken along line A-A′ of FIG. 1B, there are a plurality of device regions DVR separated from one another, whereby one first die 100 and one second die 200 are located in each of the device regions DVR. Furthermore, one device region DVR is separated from an adjacent device region DVR by the sawing regions PRX.

In some embodiments, the first die 100 is stacked on top of the second die 200 along a die stacking direction S1. In the exemplary embodiment, the bonded first die 100 and second die 200 may belong to part of the semiconductor wafer. For example, a number of device regions DVR located on the semiconductor wafer is not limited to that shown in FIG. 1B, and may be adjusted based on product requirements. Furthermore, as illustrated in FIG. 1A and FIG. 1B, dicing lines DL are separating the device regions DVR from sawing regions PRX, whereby a dicing or singulation process may be performed in the sawing regions PRX at later stages to separate the semiconductor packages.

In the exemplary embodiment, the first die 100 is formed with a semiconductor substrate 102, a first interconnection layer 104, through substrate vias 106, a first bonding layer 108 and a backside redistribution layer 110. In some embodiments, the semiconductor substrate 102 may be a bulk silicon substrate or a silicon-on-insulator (SOI) substrate, and further includes active devices (e.g., transistors or the like) and optionally passive devices (e.g., resistors, capacitors, inductors or the like) formed therein, or located thereon. In some embodiments, the first interconnection layer 104 is disposed on the semiconductor substrate 102, and contacting a top surface of the semiconductor substrate 102. In some embodiments, the formation of the first interconnection layer 104 includes forming a plurality of dielectric layers 104A and a plurality of conductive elements 104B that are alternately stacked. The number of layers of the dielectric layers 104A and the number of layers of the conductive elements 104B is not particularly limited in the disclosure, and may be adjusted based on product requirements.

In some embodiments, a material of the dielectric layers 104A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 104A may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive elements 104B may be made of conductive materials formed by electroplating or deposition, such as aluminum, titanium, copper, nickel, tungsten, and/or alloys thereof, which may be patterned using a photolithography and etching process. In some embodiments, the conductive elements 104B may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the through substrate vias 106 extend from the first interconnection layer 104 to the semiconductor substrate 102, and are embedded in the semiconductor substrate 102. Although one through substrate via 106 is illustrated in FIG. 1A, it is noted that the number of through substrate vias 106 may in fact be more than one, and may be adjusted based on product requirements. In certain embodiments, the through substrate vias 106 are electrically connected to the conductive elements 104B of the first interconnection layer 104. The through substrate vias 106 may be formed of conductive materials, such as copper, copper alloys, or the like, and may be formed by plating or deposition.

As further illustrated in FIG. 1A, the backside redistribution layer 110 is formed on a backside of the semiconductor substrate 102. For example, the through substrate vias 106 are electrically connecting the backside redistribution layer 110 to the first interconnection layer 104. In some embodiments, the formation of the backside redistribution layer 110 includes forming a plurality of dielectric layers 110A and a plurality of conductive elements 110B that are alternately stacked. The number of layers of the dielectric layers 110A and the number of layers of the conductive elements 110B is not particularly limited in the disclosure, and may be adjusted based on product requirements. Furthermore, conductive pads 110C are formed in a topmost dielectric layer 110A, and are electrically connected to the conductive elements 110B. In some embodiments, the conductive pads 110C are for example, under-ball metallurgy (UBM) patterns used for ball mount. The number of conductive pads 110C are not limited in this disclosure, and may be selected based on the design layout.

In some embodiments, a material of the dielectric layers 110A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 110A may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive elements 110B may be made of conductive materials formed by electroplating or deposition, such as aluminum, titanium, copper, nickel, tungsten, and/or alloys thereof, which may be patterned using a photolithography and etching process. In some embodiments, the conductive elements 110B may be patterned copper layers or other suitable patterned metal layers. In certain embodiments, the materials of the conductive pads 110C may include copper, nickel, titanium, tungsten, or alloys thereof or the like, and may be formed by an electroplating process, for example.

Furthermore, in some embodiments, the first bonding layer 108 of the first die 100 is formed on the first interconnection layer 104. For example, forming the first bonding layer 108 includes forming a dielectric layer 108A and a plurality of bonding pads 108B embedded in the dielectric layer 108A. In some embodiments, the bonding pads 108B may be electrically connected to the conductive elements 104B of the first interconnection layer 104 through a plurality of conductive vias 108C.

In some embodiments, the bonding pads 108B and the conductive vias 108C are made of conductive materials formed by electroplating or deposition, and include materials such as copper, copper alloys, or other suitable metallic materials which may be patterned using a photolithography and etching process. Moreover, the dielectric layer 108A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 108A is formed by suitable fabrication techniques such as spin-on coating, chemical vapor deposition (CVD), plasma-enhanced chemical vapor deposition (PECVD) or the like. The disclosure is not limited thereto. After forming the first bonding layer 108 on the first interconnection layer 104, and forming the backside redistribution layer 110 on the backside of the semiconductor substrate 102, the formation of the first die 100 is accomplished, and the first die 100 is bonded to the second die 200 through the first bonding layer 108.

In the exemplary embodiment, the second die 200 is formed with a semiconductor substrate 202, a second interconnection layer 204, and a second bonding layer 108. In some embodiments, the semiconductor substrate 202 may be a bulk silicon substrate or a silicon-on-insulator (SOI) substrate, and further includes active devices (e.g., transistors or the like) and optionally passive devices (e.g., resistors, capacitors, inductors or the like) formed therein, or located thereon. In some embodiments, the second interconnection layer 204 is disposed on the semiconductor substrate 202, and contacting a top surface of the semiconductor substrate 202. In some embodiments, the formation of the second interconnection layer 204 includes forming a plurality of dielectric layers 204A and a plurality of conductive elements 204B that are alternately stacked. The number of layers of the dielectric layers 204A and the number of layers of the conductive elements 204B is not particularly limited in the disclosure, and may be adjusted based on product requirements. The materials and method for fabricating the dielectric layers 204A and the conductive elements 204B are similar to the materials and method for fabricating the dielectric layers 104A and the conductive elements 104B. Thus, their details will not be repeated herein.

In some embodiments, the second bonding layer 206 of the second die 200 is formed on the second interconnection layer 204. For example, forming the second bonding layer 206 includes forming a dielectric layer 206A and a plurality of bonding pads 206B embedded in the dielectric layer 206A. In some embodiments, the bonding pads 206B may be electrically connected to the conductive elements 204B of the second interconnection layer 204 through a plurality of conductive vias 206C.

In some embodiments, the bonding pads 206B and the conductive vias 206C are made of conductive materials formed by electroplating or deposition, and include materials such as copper, copper alloys, or other suitable metallic materials which may be patterned using a photolithography and etching process. Moreover, the dielectric layer 206A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 108A is formed by suitable fabrication techniques such as spin-on coating, chemical vapor deposition (CVD), plasma-enhanced chemical vapor deposition (PECVD) or the like. The disclosure is not limited thereto.

In the exemplary embodiment, the first dies 100 are bonded to the second dies 200 by bonding the first bonding layer 108 to the second bonding layer 206. For example, the dielectric layer 108A is joined with the dielectric layer 206A through dielectric-to-dielectric bonding, and the bonding pads 108B are joined with the bonding pads 206B through direct metal-to-metal bonding. In some embodiments, the second dies 200 are electrically connected to the first die 100 through the first bonding layer 108 and the second bonding layer 206. Although one first die 100 is shown to be located on one second die 200 in each of the device regions DVR, it is noted that the number of first dies 100 bonded to the second dies 200 in each of the device regions DVR is not limited thereto, and may be adjusted based on product requirements.

In some embodiments, after bonding the first dies 100 to the second dies 200, a plurality of conductive bumps 112 is formed on the conductive pads 110C. In some embodiments, the conductive bumps 112 may be disposed on the conductive pads 110C by a ball placement process or reflow process. In some embodiments, the conductive bumps 112 are solder bumps, lead-free solder bumps, or micro bumps, such as controlled collapse chip connection (C4) bumps or micro bumps containing copper pillars, or the like. In some embodiments, the conductive bumps 112 are electrically connected to the backside redistribution layer 110 of the first die 100 through the conductive pads 110C.

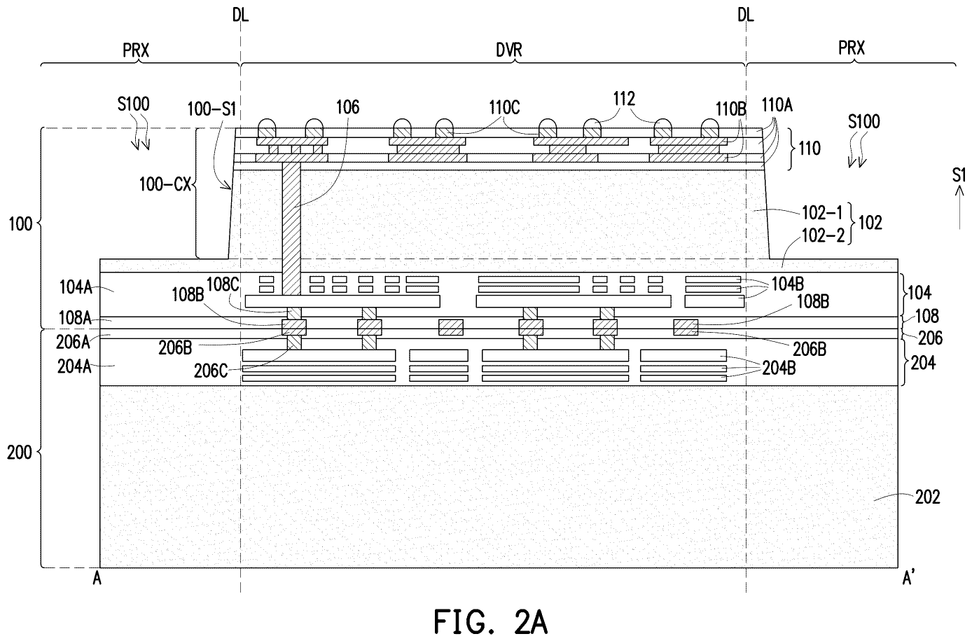

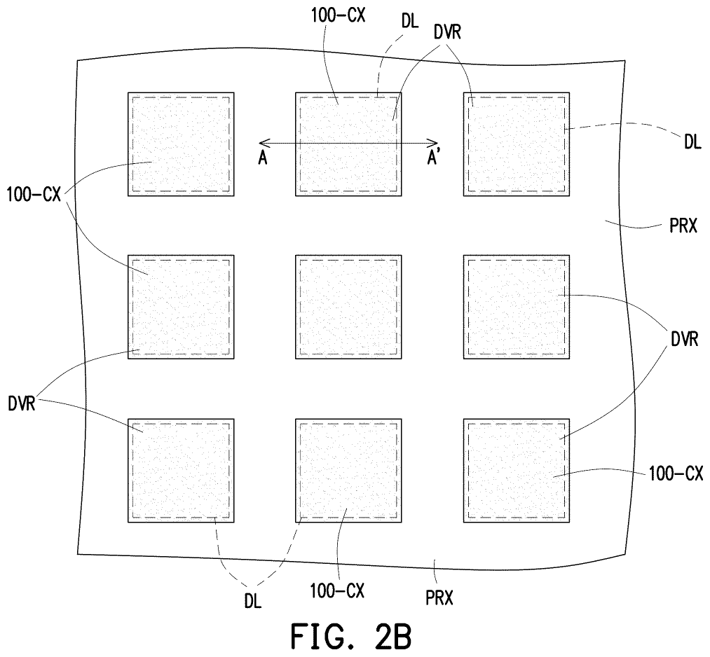

FIG. 2A is a schematic sectional taken along the line A-A′ of FIG. 2B at one stage in a method of fabricating a semiconductor package according to some exemplary embodiments of the present disclosure. FIG. 2B is a top view at one stage in a method of fabricating a semiconductor package according to some exemplary embodiments of the present disclosure. Referring to FIG. 2A and FIG. 2B, after bonding the first dies 100 on the second dies 200, a pre-sawing step S100 is performed to remove portions of the first die 100 in each of the sawing regions PRX.

In the exemplary embodiment, the pre-sawing step S100 removes portions of the backside redistribution layer 110 and portions of the semiconductor substrate 102 in the sawing regions PRX through a mechanical sawing, a blade sawing process, or the like. For example, the portions of the backside redistribution layer 110 and the portions of the semiconductor substrate 102 are removed so that the first die 100 is formed with a first core portion 100-CX having first sidewalls 100-S1, whereby the first sidewalls 100-S1 are slanted sidewalls. In some embodiments, the first core portion 100-CX includes the backside redistribution layer 110 and a first section 102-1 of the semiconductor substrate 102. The backside redistribution layer 110 and the first section 102-1 of the semiconductor substrate 102 have slanted sidewalls after the pre-sawing step S100. In certain embodiments, a second section 102-2 of the semiconductor substrate 102 remains un-sawed. In other words, the pre-sawing step S100 removes portions of the semiconductor substrate 102 to form the first core portion 100-CX, while the second section 102-2 of the semiconductor substrate 102 is retained.

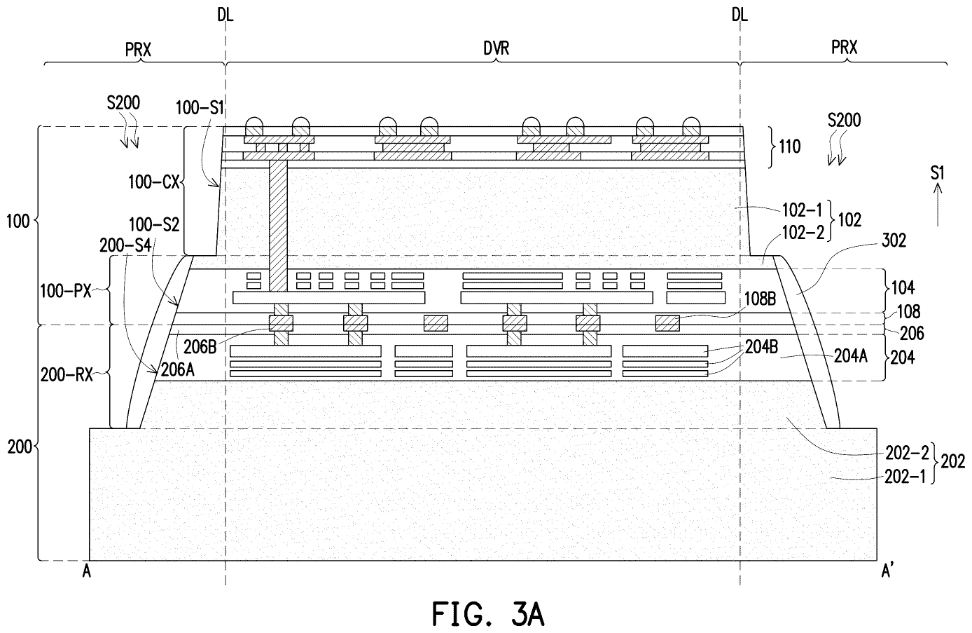

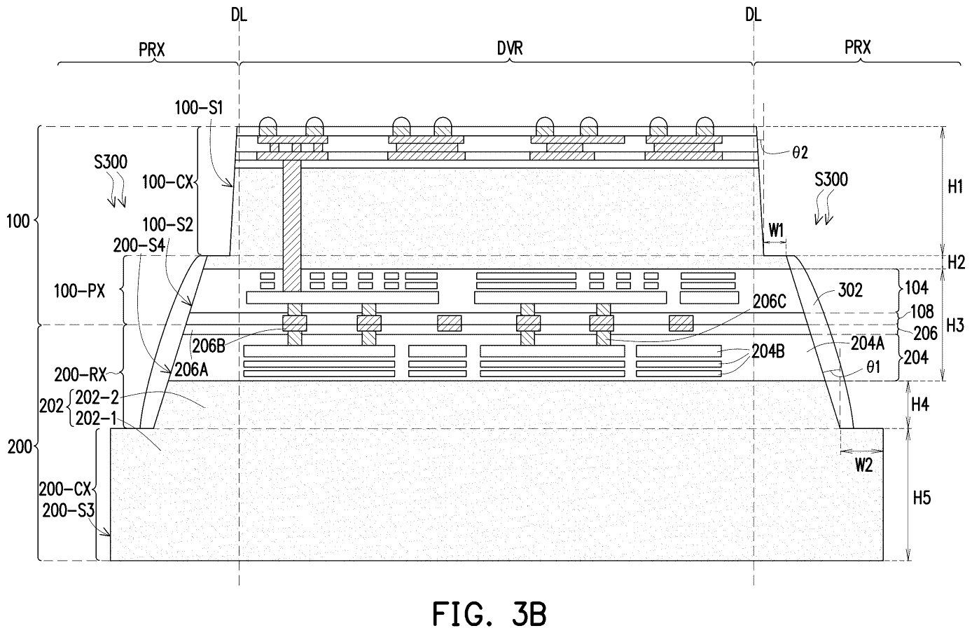

Referring to FIG. 3A, after the pre-sawing step S100, a laser grooving step S200 is performed to remove other portions of the first die 100 and portions of the second die 200 in the sawing regions PRX. For example, the laser grooving step S200 is performed by using a laser beam to remove portions of the second section 102-2 of the semiconductor substrate 102, to remove portions of the first interconnection layer 104, the first bonding layer 108, the second bonding layer 206, the second interconnection layer 204, and to remove portions of the semiconductor substrate 202 of the second die 200. In some embodiments, a picosecond laser is used in the laser grooving step S200. In some embodiments, after performing the laser grooving step S200, the first die 100 is formed with a protruding portion 100-PX and the second die 200 is formed with a retracted portion 200-RX.

In the exemplary embodiment, the protruding portion 100-PX of the first die 100 is protruding from the first core portion 100-CX and extending beyond the first sidewalls 100-S1. In certain embodiments, the protruding portion 100-PX has second sidewalls 100-S2, whereby the second sidewalls 100-S2 are slanted sidewalls. Furthermore, the protruding portion 100-PX includes the second section 102-2 of the semiconductor substrate 102, the first interconnection layer 104 and the first bonding layer 108. For example, the second section 102-2 of the semiconductor substrate 102, the first interconnection layer 104 and the first bonding layer 108 have slanted sidewalls that are aligned with one another. In some embodiments, the second section 102-2 of the semiconductor substrate 102 includes a protruding portion protruding from sidewalls (first sidewalls 100-S1) of the first section 102-1, and a step height difference exists between a top surface of protruding portion of the second section 102-2 and a top surface of the first section 102-1. Furthermore, a lateral dimension of the second section 102-2 is greater than a lateral dimension of the first section 102-1.

In some embodiments, after the laser grooving step S200, the second die 200 is formed with a retracted portion 200-RX having retracted sidewalls 200-S4 (or fourth sidewalls). As shown in FIG. 3A, the retracted sidewalls 200-S4 of the second die 200 are slanted sidewalls, whereby the retracted sidewalls 200-S4 are aligned with the second sidewalls 100-S2 of the protruding portion 100-PX. In some embodiments, the retracted portion 200-RX includes a second part 202-2 of the semiconductor substrate 202, the second interconnection layer 204 and the second bonding layer 206. For example, the second part 202-2 of the semiconductor substrate 202, the second interconnection layer 204 and the second bonding layer 206 have slanted sidewalls that are aligned with one another. In some embodiments, the laser grooving step S200 removes portions of the semiconductor substrate 202 of the second die 200 to form the retracted portion 200-RX, while a first part 202-1 of the semiconductor substrate 202 is retained. In certain embodiments, the second part 202-2 of the semiconductor substrate 202 is a retracted portion retracted from sidewalls of the first part 202-1, and a step height difference exists between a top surface of the first part 202-1 and a top surface of the retracted portion of the second part 202-2.

In some embodiments, during the laser grooving step S200, a debris formed by removing the portions of the first die 100 and portions of the second die 200 is deposited back onto the second sidewalls 100-S2 of the first die 100 and onto the retracted sidewalls 200-S4 of the second die 200 to form a recast film 302. For example, the recast film 302 is formed to cover and contact the second sidewalls 100-S2 of the first die 100 and the retracted sidewalls 200-S4 of the second die 200. In certain embodiments, the recast film 302 cover and contacts the slanted sidewalls of the second section 102-2 of the semiconductor substrate 102, the slanted sidewalls of the first interconnection layer 104, the slanted sidewalls of the first bonding layer 108, the slanted sidewalls of the second bonding layer 206, the slanted sidewalls of the second interconnection layer 204, and the slanted sidewalls of the second part 202-2 of the semiconductor substrate 202.

Referring to FIG. 3B, in a subsequent step, a die sawing step S300 is performed to saw through the semiconductor substrate 202 of the second die 200 in the sawing regions PRX. For example, the structure shown in FIG. 3A may be diced or singulated by cutting through the sawing regions PRX to separate out the package in one device region DVR from an adjacent device region DVR. In some embodiments, after performing the die sawing step S300, the second die 200 is formed with a second core portion 200-CX having third sidewalls 200-S3, wherein the retracted portion 200-RX is retracted from the third sidewalls 200-S3. In certain embodiments, the second core portion 200-CX includes the first part 202-1 of the semiconductor substrate 202. For example, a lateral dimension of the second part 202-2 of the semiconductor substrate 202 is smaller than a lateral dimension of the first part 202-1 after the die sawing step S300. Furthermore, in some embodiments, a lateral dimension of the second section 102-2 of the semiconductor substrate 102 may be substantially equal to, or smaller than a lateral dimension of the second part 202-2 of the semiconductor substrate 202.

In the exemplary embodiment, a first angle of the retracted sidewalls 200-S4 (or fourth sidewalls) of the second die 200 relative to a die stacking direction S1 (shown in FIG. 3A) is θ1, and a second angle of the first sidewalls 100-S1 of the first die 100 relative to a die stacking direction S1 is θ2. In some embodiments, the first angle θ1 is different from the second angle θ2, and the first angle θ1 may be greater than the second angle θ2. For example, the first angle θ1 and the second angle θ2 satisfies the following relationship: θ1≥(2*θ2)>0°. In other words, the first angle θ1 is equal to or greater than two times of the second angle θ2.

In some embodiments, the second part 202-2 of the semiconductor substrate 202 has slanted sidewalls having the first angle θ1 relative to the die stacking direction S1, and the first section 102-1 of the semiconductor substrate 102 has slanted sidewalls having the second angle θ2 relative to the die stacking direction S1. Similarly, the first interconnection layer 104, the first bonding layer 108, the second bonding layer 206 and the second interconnection layer 204 have slanted sidewalls having the first angle θ1 relative to the die stacking direction S1, while the backside redistribution layer 110 has slanted sidewalls having the second angle θ2 relative to the die stacking direction S1.

As further illustrated in FIG. 3B, the first core portion 100-CX has a height of H1, or the backside redistribution layer 110 and the first section 102-1 of the first semiconductor substrate 102 has a total height of H1. Furthermore, the second section 102-2 of the semiconductor substrate 102 has a height of H2, and the height H1 and the height H2 satisfies the following relationship: 0.9≥(H1/(H1+H2))≥0.8. In some embodiments, a total height of the first bonding layer 108, the second bonding layer 206, the first interconnection layer 104, the second interconnection layer 204 is H3, while a height of the second part 202-2 of the semiconductor substrate 202 is H4. In some embodiments, a sum (H2+H3+H4) of the height H2, the total height H3 and the height H4 is less than 100 μm. Furthermore, the first part 202-1 of the semiconductor substrate 202 has a height of H5, whereby the height H4 and the height H5 satisfies the following relationship: 0.03≥(H4/(H4+H5))≥0.01. By controlling the height H1, height H2, total height H3, height H4 and the height H5 to fulfill the above relationships, an amount of debris formed during the laser grooving step S200 is minimized, and a bending strength of the semiconductor package is further increased.

In some embodiments, the protruding portion 100-PX of the first die 100 has a protruding width of W1, and the retracted portion 200-RX of the second die 200 has a retracted width of W2, and the protruding width W1 and the retracted width W2 satisfies the following relationship: 1>((2*W1)/W2)>0. In some embodiments, the protruding width W1 corresponds to a width of the second section 102-2 of the semiconductor substrate 102 that is protruding out from the first sidewalls 100-S1 of the first core portion 100-CX. Furthermore, the retracted width W2 corresponds to a portion of the first part 202-1 of the semiconductor substrate 202 that is uncovered by the retracted portion 200-RX. In some embodiments, the recast film 302 covers less than 50% of a top surface area of the uncovered portion of the first part 202-1 of the semiconductor substrate 202 corresponding to the retracted width W2. In some embodiments, the recast film 302 covers less than 40%, or less than 30% of a top surface area of the uncovered portion of the first part 202-1 of the semiconductor substrate 202 corresponding to the retracted width W2.

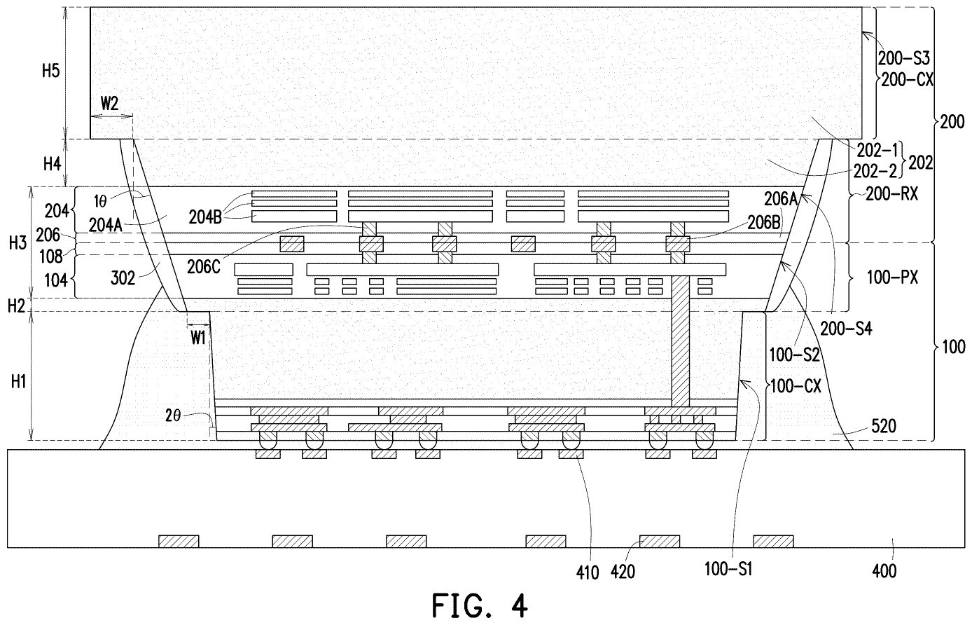

Referring to FIG. 4, after performing the laser grooving step S200 and the die sawing step S300, the structure shown in FIG. 3B is flipped and bonded onto a substrate 400. For example, the first die 100 and the second die 200 are bonded on and electrically connected to the substrate 400 through the conductive bumps 112. In some embodiments, the substrate 400 includes contact pads 410, contact pads 420, metallization layers and vias (not shown). In some embodiments, the contact pads 410 and the contact pads 420 are respectively distributed on two opposite sides of the circuit substrate 400, and are exposed for electrically connecting with later-formed elements/features. In some embodiments, the metallization layers and the vias are embedded in the circuit substrate 400 and together provide routing function for the circuit substrate 400, wherein the metallization layers and the vias are electrically connected to the contact pads 410 and the contact pads 420. In other words, at least some of the contact pads 410 are electrically connected to some of the contact pads 420 through the metallization layers and the vias. In some embodiments, the contact pads 410 and the contact pads 420 may include metal pads or metal alloy pads. In some embodiments, the materials of the metallization layers and the vias may be substantially the same or similar to the material of the contact pads 410 and the contact pads 420. In some embodiments, the first die 100 is bonded to the substrate 400 through physically connecting the conductive bumps 112 to the contact pads 410 to form a stacked structure. In some embodiments, the substrate 400 is such as an organic flexible substrate or a printed circuit board. In such embodiments, the conductive bumps 112 are, for example, chip connectors.

As further illustrated in FIG. 4, an underfill 520 is formed to fill up the spaces in between the first die 100 and the substrate 400. In some embodiments, the underfill 520 fills up the spaces in between adjacent conductive bumps 112. In certain embodiments, the underfill 520 is covering and contacting the first sidewalls 100-S1 of the first die 100, covering and contacting the first core portion 100-CX of the first die 100, and may be covering and contacting the recast film 302. However, the disclosure is not limited thereto, and in alternative embodiments, the underfill 520 is partially covering and contacting the first core portion 100-CX of the first die 100, and is spaced apart (or physically separated) from the recast film 302.

Referring to FIG. 5, in a subsequent step, an encapsulant 530 (or molding compound) is formed on the substrate 400 to surround the first die 100 and the second die 200. For example, the encapsulant 530 is directly contacting the first part 202-1 of the semiconductor substrate 202, and is laterally surrounding and contacting the recast film 302 and the underfill 520. In some embodiments, the encapsulant 530 is formed through, for example, a compression molding process or transfer molding. In one embodiment, a curing process is performed to cure the encapsulant 530.

In some embodiments, a material of the encapsulant 530 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the encapsulant 530 may include an acceptable insulating encapsulation material. In some embodiments, the encapsulant 530 may further include inorganic filler or inorganic compound (e.g. silica, clay, and so on) which can be added therein to optimize coefficient of thermal expansion (CTE) of the encapsulant 530. The disclosure is not limited thereto.

In a subsequent step, after forming the encapsulant 530, conductive terminals 430 may be formed on the contact pads 420 of the substrate 400. Through the contact pads 410 and the contact pads 420, some of the conductive terminals 430 are electrically connected to the first die 100 and the second die 200. In some embodiments, the conductive terminals 430 are, for example, solder balls or ball grid array (BGA) balls. After forming the encapsulant 530 and the conductive terminals 430, a semiconductor package SM1 in accordance with some embodiments of the present disclosure is accomplished.

In the semiconductor package SM1, since a pre-sawing step S100, a laser grooving step S200 and a die sawing step S300 are preformed to form a stacked die structure having the designated angles (θ1, θ2), heights (H1, H2, H3, H4 and H5) and widths (W1, W2), the mechanical saw induced bounding interface damage is mitigated, the amount of debris formed on the package sidewalls is reduced, and a package bending strength is increased. By designing the semiconductor package SM1 to include the above sidewall profiles, the reliability of the package can be further improved.

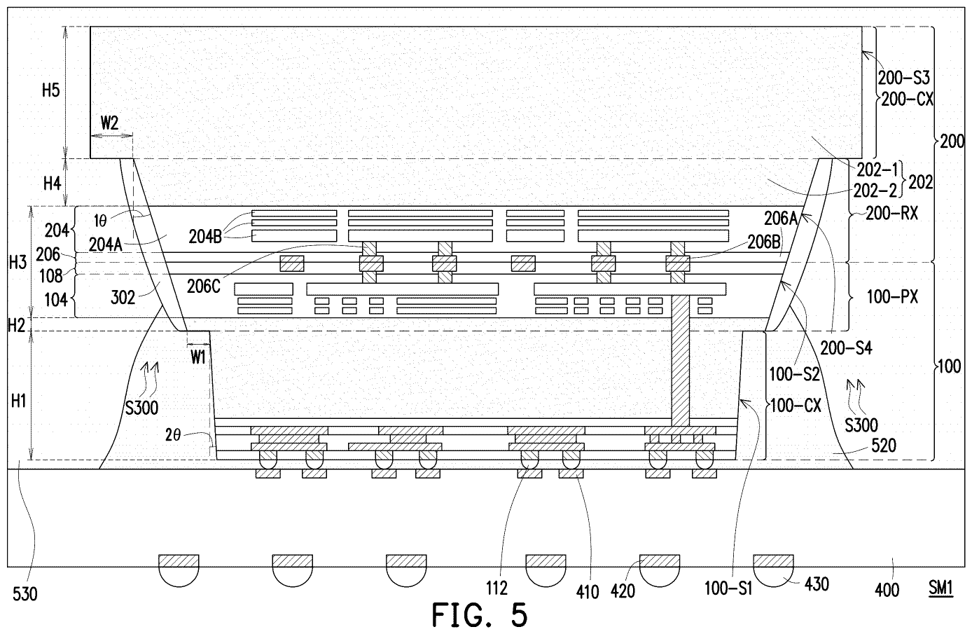

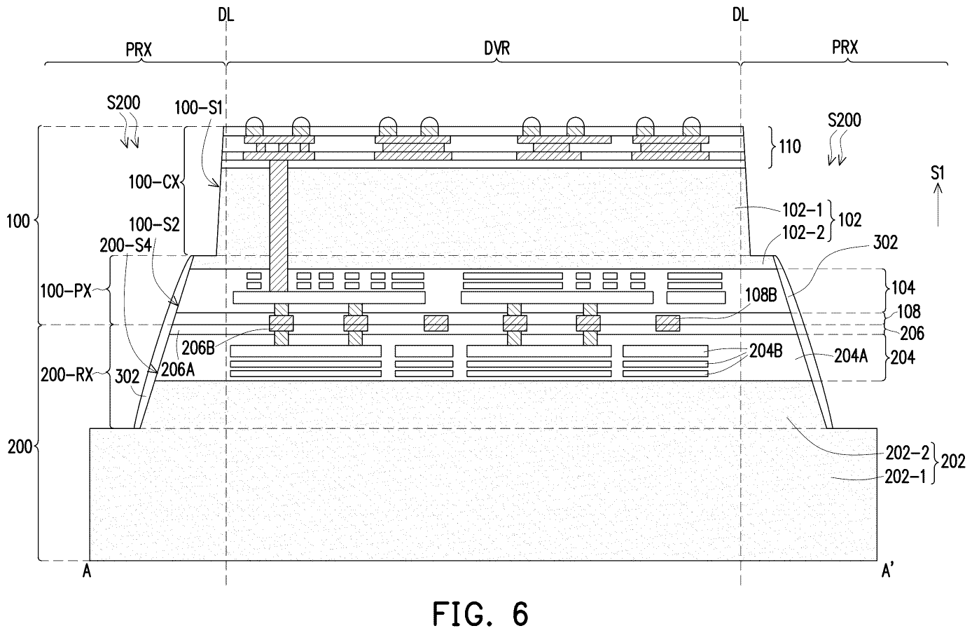

FIG. 6 to FIG. 7 are schematic sectional views of various stages in a method of fabricating a semiconductor package according to some other embodiments of the present disclosure. The method shown in FIG. 6 to FIG. 7 is similar to the method shown in FIG. 1A to FIG. 5. Therefore, the same reference numerals are used to refer to the same or liked parts, and its detailed description will be omitted herein.

As illustrated in FIG. 6, the same steps shown in FIG. 1A to FIG. 2B may be performed so that portions of the first die 100 are removed by the pre-sawing step S100. Thereafter, a laser grooving step S200 is performed to remove other portions of the first die 100 and portions of the second die 200. In the embodiment shown in FIG. 3A, the laser grooving step S200 is performed using a picosecond laser, for example. However, the disclosure is not limited thereto. In the embodiment shown in FIG. 6, the laser grooving step S200 is performed by utilizing a laser having an ultra-short laser wavelength, such as a femtosecond laser. By using the femtosecond laser in the laser grooving step S200, an amount of recast film 302 (or debris) formed on the second sidewalls 100-S2 of the first die 100 and on the retracted sidewalls 200-S4 of the second die 200 is reduced. For example, in one embodiment, the recast film 302 covers less than 30% of a top surface area of the uncovered portion of the first part 202-1 of the semiconductor substrate 202 corresponding to the retracted width W2 (shown in FIG. 3B). In certain embodiments, the recast film 302 covers less than 20%, or less than 10% of a top surface area of the uncovered portion of the first part 202-1 of the semiconductor substrate 202 corresponding to the retracted width W2.

Thereafter, referring to FIG. 7, the die sawing step S300 described in FIG. 3B and the bonding to the substrate 400, as well as the formation of the underfill 520, the encapsulant 530 and conductive terminals 430 described in FIG. 4 and FIG. 5 may be performed in the same way to form the semiconductor package SM2. In the exemplary embodiment, the first die 100 having the first core portion 100-CX and the protruding portion 100-PX, and the second die 200 having the second core portion 200-CX and the retracted portion 200-RX are formed with the same angles (θ1, θ2), heights (H1, H2, H3, H4 and H5) and widths (W1, W2) as with the semiconductor package SM1.

As such, in the semiconductor package SM2, since a pre-sawing step S100, a laser grooving step S200 and a die sawing step S300 are preformed to form a stacked die structure having the designated angles (θ1, θ2), heights (H1, H2, H3, H4 and H5) and widths (W1, W2), the mechanical saw induced bounding interface damage is mitigated, the amount of debris formed on the package sidewalls is reduced, and a package bending strength is increased. By designing the semiconductor package SM2 to include the above sidewall profiles, the reliability of the package can be further improved.

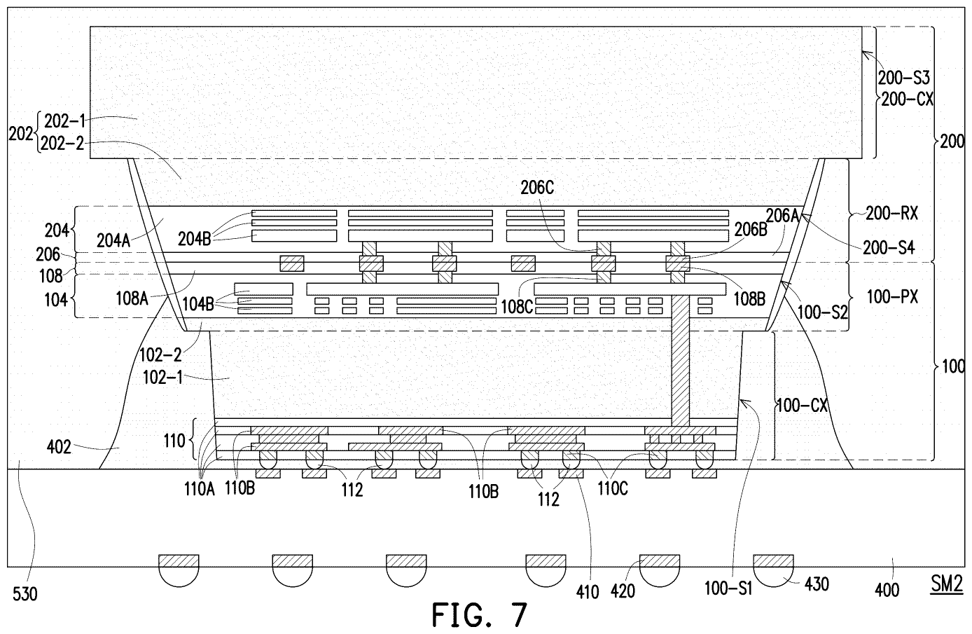

FIG. 8 to FIG. 11 are schematic sectional views of various stages in a method of fabricating a semiconductor package according to some other embodiments of the present disclosure. The method shown in FIG. 8 to FIG. 11 is similar to the method shown in FIG. 1A to FIG. 5. Therefore, the same reference numerals are used to refer to the same or liked parts, and its detailed description will be omitted herein. The difference between the method is that a pre-sawing step S100 including a rough sawing step S100-A and a fine sawing step S100-B is performed in the method shown in FIG. 8 to FIG. 11.

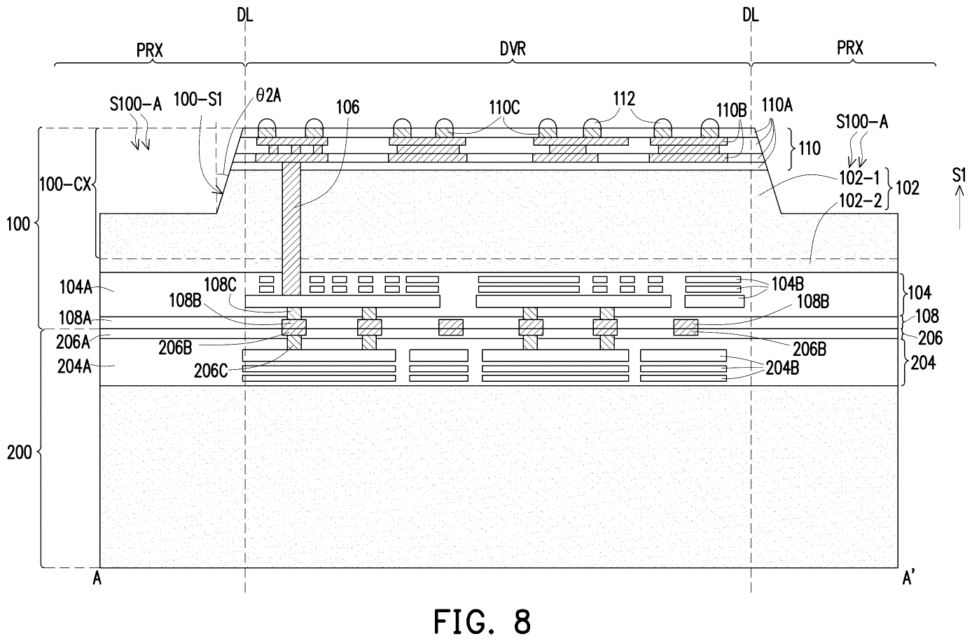

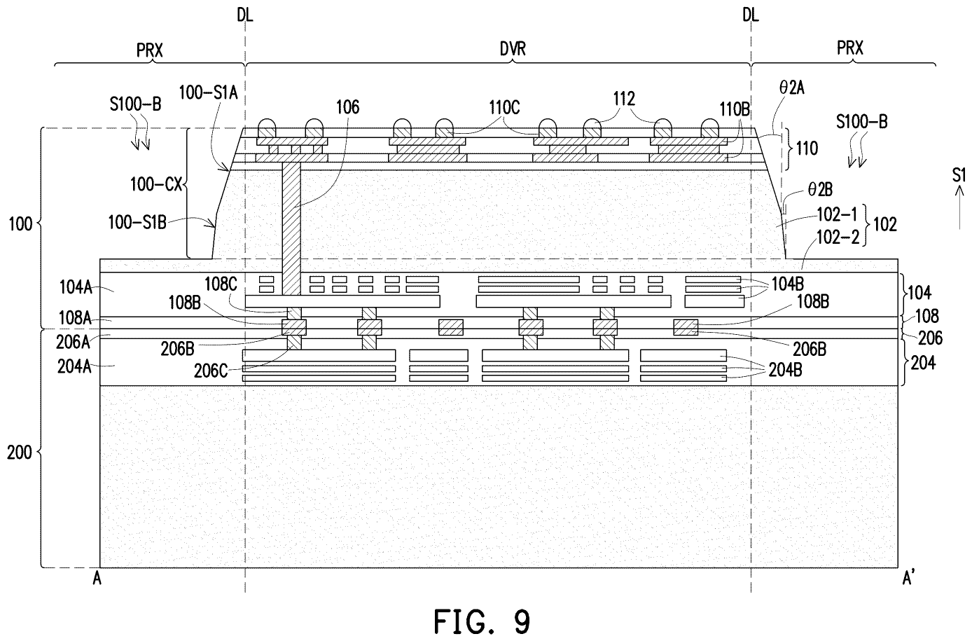

Referring to FIG. 8, after bonding the first die 100 onto the second die 200 in the same manner shown in FIG. 1A, a rough sawing step S100-A is first performed to roughly remove portions of the semiconductor substrate 102 and portions of the backside redistribution layer 110. Subsequently referring to FIG. 9, a fine sawing step S100-B is performed to further remove portions of the first section 102-1 of the semiconductor substrate 102. In some embodiments, a sawing depth of the rough sawing step S100-A is greater than a sawing depth of the fine sawing step S100-B. As such, through the rough sawing step S100-A and the fine sawing step S100-B, the first sidewall 100-S1 having a first angled portion 100-S1A and a second angled portion 100-S1B is formed on the first core portion 100-CX. In some embodiments, the rough sawing step S100-A is performed using a rough sawing blade, while the fine sawing step S100-B is performed using a fine sawing blade.

In the exemplary embodiment, the rough sawing step S100-A forms the first angled portion 100-S1A having an angle of θ2A relative to the die stacking direction S1, while the fine sawing step S100-B forms the second angled portion 100-S1B having an angle of θ2B relative to the die stacking direction S1. For example, the angle θ2A is different from the angle θ2B. In some embodiments, the angle θ2A is greater than the angle θ2B. In other words, the rough sawing step S100-A forms slanted sidewalls at a greater angle than the fine sawing step S100-B.

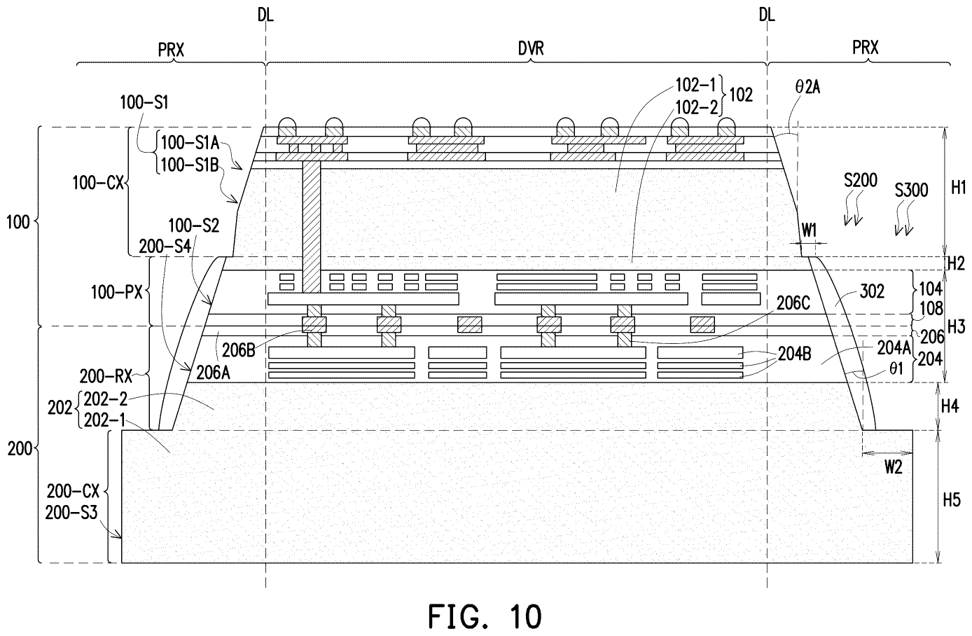

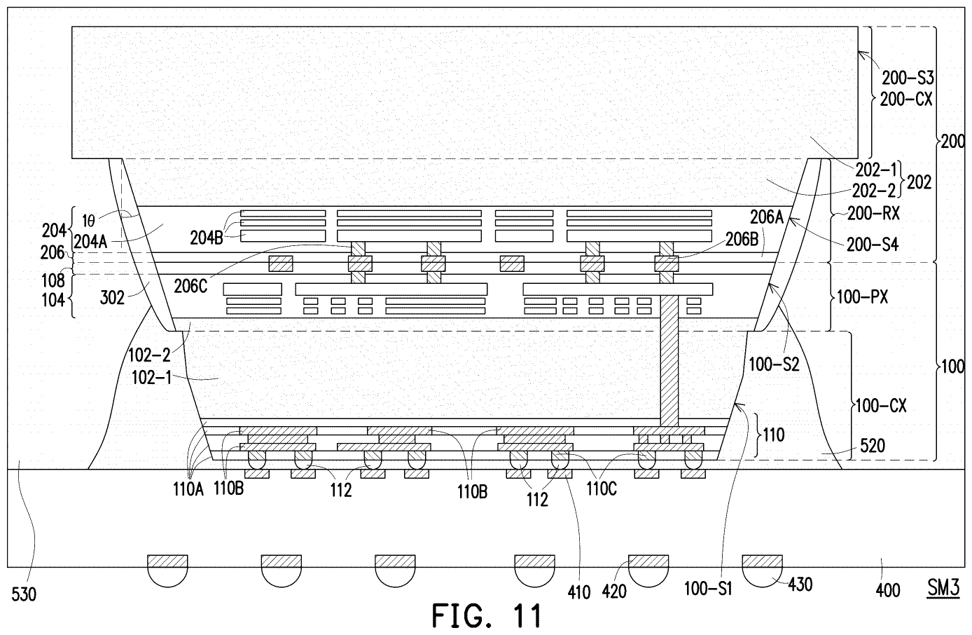

Referring to FIG. 10, after performing the rough sawing step S100-A and the fine sawing step S100-B, the laser grooving step S200 and the die sawing step S300 may be performed in the same manner described in FIG. 3A to FIG. 3B, to form the first die 100 and the second die 200 having the same first angle θ1, heights (H1, H2, H3, H4 and H5) and widths (W1, W2). In the exemplary embodiment, both of the angle θ2A and angle θ2B are smaller than the first angle θ1 of the retracted sidewalls 200-S4 of the second die 200. Furthermore, in some embodiments, the angle θ2B and the first angle θ1 satisfies the following relationship: θ1≥(2*θ2B)>0°. Referring to FIG. 11, in a subsequent step, the bonding to the substrate 400, as well as the formation of the underfill 520, the encapsulant 530 and conductive terminals 430 described in FIG. 4 and FIG. 5 may be performed in the same way to form the semiconductor package SM3.

In the semiconductor package SM3, since a pre-sawing step S100, a laser grooving step S200 and a die sawing step S300 are preformed to form a stacked die structure having the designated angles (θ1, θ2A, θ2B), heights (H1, H2, H3, H4 and H5) and widths (W1, W2), the mechanical saw induced bounding interface damage is mitigated, the amount of debris formed on the package sidewalls is reduced, and a package bending strength is increased. By designing the semiconductor package SM3 to include the above sidewall profiles, the reliability of the package can be further improved.

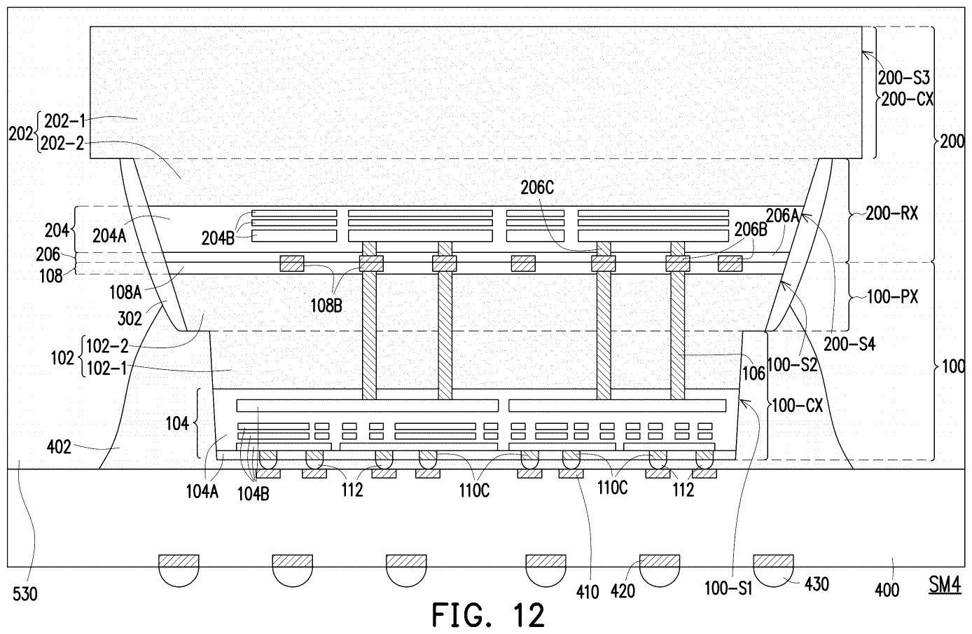

FIG. 12 is a schematic sectional view of a semiconductor package according to some other embodiments of the present disclosure. The semiconductor package SM4 illustrated in FIG. 12 is similar to the semiconductor package SM1 illustrated in FIG. 5. Therefore, the same reference numerals are used to refer to the same or liked parts, and its detailed description is omitted herein.

In the previous embodiments, the first die 100 is bonded to the second die 200 in a face-to-face manner, whereby the first interconnection layer 104 and the second interconnection layer 204 are sandwiched between the semiconductor substrate 102 and the semiconductor substrate 202. In other words, an active surface of the first die 100 is facing an active surface of the second die 200. However, the disclosure is not limited thereto, and in the embodiment shown in FIG. 12, the first die 100 is bonded to the second die 200 in a face-to-back manner. For example, in the semiconductor package SM4 shown in FIG. 12, the semiconductor substrate 102 of the first die 100 is located in between the first interconnection layer 104 and the second interconnection layer 204.

In the exemplary embodiment, the first die 100 is formed with a first core portion 100-CX having first sidewalls 100-S1, and a protruding portion 100-PX having second sidewalls 100-S2, while the second die 200 is formed with a second core portion 200-CX having third sidewalls 200-S3, and a retracted portion 200-RX having retracted sidewalls 200-RX. In some embodiments, the first core portion 100-CX includes the first section 102-1 of the semiconductor substrate 102 and the first interconnection layer 104, while the protruding portion 100-PX includes the second section 102-2 of the semiconductor substrate 102. In certain embodiments, the second core portion 200-CX and the retracted portion 200-RX of the second die 200 shown in FIG. 12 includes the same components as with the second core portion 200-CX and the retracted portion 200-RX of the second die 200 shown in FIG. 5, thus their details will be omitted herein. Similar to the embodiment shown in FIG. 5, the retracted sidewalls 200-S4 (or fourth sidewalls) of the second die 200 has the same first angle θ1 relative to the die stacking direction S1, and the first sidewalls 100-S1 of the first die 100 has the same second angle θ2 relative to the die stacking direction S1.

In the semiconductor package SM4, since a pre-sawing step S100, a laser grooving step S200 and a die sawing step S300 are preformed to form a stacked die structure having the designated angles (θ1, θ2), heights (H1, H4 and H5) and widths (W1, W2), the mechanical saw induced bounding interface damage is mitigated, the amount of debris formed on the package sidewalls is reduced, and a package bending strength is increased. By designing the semiconductor package SM4 to include the above sidewall profiles, the reliability of the package can be further improved.

In the above-mentioned embodiments, the semiconductor package having die-to-die bonding structures is formed through a pre-sawing step, a laser grooving step and a die sawing step. As such, the semiconductor package can be formed with designated angles, heights and widths. As a result, the mechanical saw induced bounding interface damage is mitigated, the amount of debris formed on the package sidewalls is reduced, and a package bending strength is increased. Overall, the semiconductor packages have optimized sidewall profiles, and the reliability of the package can be further improved.

In accordance with some embodiments of the present disclosure, a semiconductor package includes a first die and a second die. The first die is stacked on the second die. The first die includes a first core portion and a protruding portion. The first core portion has first sidewalls, while protruding portion is protruding from the first core portion and extending beyond the first sidewalls, wherein the protruding portion has second sidewalls. The second die includes a second core portion and a retracted portion. The second portion has third sidewalls, while the retracted portion is retracted from the third sidewalls, wherein the retracted portion of the second die has fourth sidewalls, and the fourth sidewalls are aligned with the second sidewalls.

In accordance with some other embodiments of the present disclosure, a semiconductor package includes a first die and a second die. The first die is stacked on the second die. The first die includes a first semiconductor substrate and a first interconnection layer. The first semiconductor substrate has a first section and a second section, wherein a lateral dimension of the second section is greater than a lateral dimension of the first section. The first interconnection layer is disposed on the first semiconductor substrate. The second die includes a second semiconductor substrate and a second interconnection layer. The second semiconductor substrate has a first part and a second part, wherein a lateral dimension of the second part is smaller than a lateral dimension of the first part. The second interconnection layer is disposed on the second semiconductor substrate, wherein the second interconnection layer is sandwiched between the first interconnection layer and the second semiconductor substrate.

In accordance with yet another embodiment of the present disclosure, a method of fabricating a semiconductor package includes the following steps. A first die is bonded onto a second die. A pre-sawing step is performed to remove portions of the first die, wherein after the re-sawing step, the first die is formed with a first core portion having first sidewalls. A laser grooving step is preformed to remove other portions of the first die and portions of the second die, wherein after performing the laser grooving step, the first die has a protruding portion protruding from the first core portion and extending beyond the first sidewalls, and the protruding portion has second sidewalls, and wherein the second die is formed with a retracted portion having retracted sidewalls, and the retracted sidewalls are aligned with the second sidewalls. A die sawing step is performed to saw through the second die, wherein after the die sawing step, the second die is formed with a second core portion having third sidewalls, wherein the retracted portion is retracted from the third sidewalls.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first die comprising:
a first core portion having first sidewalls; and
a protruding portion protruding from the first core portion and extending beyond the first sidewalls, wherein the protruding portion has second sidewalls;
a second die, wherein the first die is stacked on the second die, and the second die comprising:
a second core portion having third sidewalls; and
a retracted portion retracted from the third sidewalls, wherein the retracted portion of the second die has fourth sidewalls, and the fourth sidewalls are aligned with the second sidewalls.

2. The semiconductor package according to claim 1, wherein the second sidewalls and the fourth sidewalls are slanted sidewalls.

3. The semiconductor package according to claim 1, wherein a first angle of the fourth sidewalls relative to a die stacking direction is θ1, and a second angle of the first sidewalls relative to a die stacking direction is θ2, and wherein the first angle θ1 and the second angle θ2 satisfies the following relationship: θ1≥(2*θ2)>0°.

4. The semiconductor package according to claim 1, wherein the protruding portion has a protruding width of W1, the retracted portion has a retracted width of W2, and the protruding width W1 and the retracted width W2 satisfies the following relationship: 1>((2*W1)/W2)>0.

5. The semiconductor package according to claim 1, further comprising a recast film covering and contacting the second sidewalls and the fourth sidewalls.

6. The semiconductor package according to claim 5, further comprising an underfill covering the recast film, and covering and contacting the first sidewalls.

7. The semiconductor package according to claim 1, wherein the first core portion comprises a backside redistribution layer and a first section of a first semiconductor substrate, the protruding portion comprises a second section of the first semiconductor substrate, a first interconnection layer and a first bonding layer, and wherein the first core portion has a height of H1, the second section of the first semiconductor substrate has a height of H2, and the height H1 and the height H2 satisfies the following relationship: 0.9≥(H1/(H1+H2))≥0.8.

8. A semiconductor package, comprising:
a first die, comprising:
a first semiconductor substrate having a first section and a second section, wherein a lateral dimension of the second section is greater than a lateral dimension of the first section; and
a first interconnection layer disposed on the first semiconductor substrate;
a second die, wherein the first die is stacked on the second die, and comprising:
a second semiconductor substrate having a first part and a second part, wherein a lateral dimension of the second part is smaller than a lateral dimension of the first part; and
a second interconnection layer disposed on the second semiconductor substrate, wherein the second interconnection layer is sandwiched between the first interconnection layer and the second semiconductor substrate.

9. The semiconductor package according to claim 8, wherein the first die further comprises a backside redistribution layer located on the first section of the first semiconductor substrate, and a first bonding layer located on the first interconnection layer, and the second die further comprises a second bonding layer located on the second interconnection layer, and the first bonding layer is directly bonded to the second bonding layer.

10. The semiconductor package according to claim 9, wherein a total height of the first bonding layer, the second bonding layer, the first interconnection layer, the second interconnection layer is H3, a height of the second section of the first semiconductor substrate is H2, a height of the second part of the second semiconductor substrate is H4, wherein a sum (H2+H3+H4) of the height H2, the total height H3 and the height H4 is less than 100 μm.

11. The semiconductor package according to claim 9, wherein the backside redistribution layer and the first section of the first semiconductor substrate has a total height of H1, the second section of the first semiconductor substrate has a height of H2, and the height H1 and the height H2 satisfies the following relationship: 0.9≥(H1/(H1+H2))≥0.8.

12. The semiconductor package according to claim 8, wherein the first part of the second semiconductor substrate has a height of H5, the second part of the second semiconductor substrate has a height of H4, and the height H4 and the height H5 satisfies the following relationship:
0.03≥(H4/(H4+H5))≥0.01.

13. The semiconductor package according to claim 8, wherein the second section of the first semiconductor substrate includes a protruding portion protruding from sidewalls of the first section, and a step height difference exists between a top surface of protruding portion of the second section and a top surface of the first section, and wherein the second part of the second semiconductor substrate is a retracted portion retracted from sidewalls of the first part, and a step height difference exists between a top surface of the first part and a top surface of the retracted portion.

14. The semiconductor package according to claim 8, wherein the second part of the second semiconductor substrate has a first slanted sidewall having an angle of θ1 relative to a die stacking direction, and the first section of the first semiconductor substrate has a second slanted sidewall having an angle of θ2 relative to the die stacking direction, and wherein the angle θ1 is different from the angle θ2.

15. The semiconductor package according to claim 8, wherein the lateral dimension of the second section is smaller than the lateral dimension of the second part.

16. A method of fabricating a semiconductor package, comprising:
bonding a first die onto a second die;
performing a pre-sawing step to remove portions of the first die, wherein after the pre-sawing step, the first die is formed with a first core portion having first sidewalls;
performing a laser grooving step to remove other portions of the first die and portions of the second die, wherein after performing the laser grooving step, the first die has a protruding portion protruding from the first core portion and extending beyond the first sidewalls, and the protruding portion has second sidewalls, and wherein the second die is formed with a retracted portion having retracted sidewalls, and the retracted sidewalls are aligned with the second sidewalls; and
performing a die sawing step to saw through the second die, wherein after the die sawing step, the second die is formed with a second core portion having third sidewalls, wherein the retracted portion is retracted from the third sidewalls.

17. The method according to claim 16, wherein the laser grooving step includes using a femtosecond laser for removing the other portions of the first die and the portions of the second die.

18. The method according to claim 16, wherein during the laser grooving step, a debris formed by removing the portions of the first die and portions of the second die is deposited back onto the second sidewalls of the first die and onto the retracted sidewalls of the second die to form a recast film.

19. The method according to claim 16, wherein the pre-sawing step comprises a rough sawing step and a fine sawing step to form the first core portion having the first sidewalls, wherein the rough sawing step forms a first angled portion on the first core portion, and the fine sawing step forms a second angled portion on the first core portion, wherein the first angled portion and the second angled portion have different angles relative to a die stacking direction.

20. The method according to claim 16, wherein the protruding portion is formed with a protruding width of W1, the retracted portion is formed with a retracted width of W2, and the protruding width W1 and the retracted width W2 satisfies the following relationship: 1>((2*W1)/W2)>0.
